(19) United States
(12) Patent Application Publication
(10) Pub. No.: US 2004/0003839 A1
(43) Pub. Date: Jan. 8, 2004

(54) Nano photovoltaic/solar cells

(76) Inventor: Lawrence F. Curtin, Key Biscayne, FL (US)

Correspondence Address: Richard C. Litman, LITMAN LAW OFFICES, LTD., P.O. Box 15035, Arlington, VA, 22215, US

(21) Appl. No.: 10/357,460

(22) Filed: Feb. 4, 2003

Related U.S. Application Data
(63) Continuation-in-part of application No. 10/189,219, filed on Jul. 5, 2002.

(51) Int. Cl. H01L 31/00

(52) U.S. Cl. 136/250; 136/256; 438/63

(57) ABSTRACT

Nano photovoltaic/solar cells each include a layer of plastic, conductive paint on the layer of plastic, dielectric adhesive colloid film on the conductive paint, nano photovoltaic/solar elements in the dielectric adhesive colloid film and contacting the conductive paint, clear conductive coating on the nano photovoltaic/solar elements, and a contact transfer release sheet on the clear conductive coating. The nano photovoltaic/solar elements each include a conductive bottom, a P type layer on the conductive bottom, an N type layer on the P type layer, and a clear conductive top on the N type layer. The nano photovoltaic/solar elements may include more than one P and N junction between the conductive bottom and clear conductive top.

### CROSS REFERENCE TO RELATED APPLICATIONS

This application is a continuation-in-part of application Ser. No. 10/189,219, filed Jul. 5, 2002, and is related to the following patents, the subject matter of which are hereby incorporated by reference: U.S. Pat. No. 6,013,871, entitled METHOD OF PREPARING A PHOTOVOLTAIC DEVICE, U.S. Pat. No. 6,160,215, entitled METHOD OF MAKING PHOTOVOLTAIC DEVICE, and U.S. Pat. No. 6,380,477 B1, entitled METHOD OF MAKING PHOTOVOLTAIC DEVICE.

### BACKGROUND OF THE INVENTION

1. Field of the Invention

The present invention relates to photovoltaic/solar cells and, more particularly to photovoltaic/solar cells configured using nanotechnology.

2. Description of the Related Art

The use of photovoltaic or solar cells, devices that can absorb and convert light into electrical power, has been limited because of high production costs. Even the fabrication of the simplest semiconductor cell is a complex process that has to take place under exactly controlled conditions, such as high vacuum and temperatures between 400° C. and 1,400° C. A need exists for providing inexpensive manufacturing processes for manufacturing photovoltaic/solar cells. The related art is represented by the following references of interest.

U.S. Pat. No. 4,228,570, issued on Oct. 21, 1980 to Rhodes R. Chamberlain et al., describes an apparatus for forming a large area photovoltaic panel into a plurality of smaller photovoltaic cells. Chamberlain et al. does not suggest nano photovoltaic/solar cells according to the claimed invention.

U.S. Pat. No. 4,260,429, issued on Apr. 7, 1981 to Richard L. Moyer, describes an electrode for a photovoltaic cell and a method for its manufacture. Moyer does not suggest nano photovoltaic/solar cells according to the claimed invention.

U.S. Pat. No. 4,283,591, issued on Aug. 11, 1981 to Karl W. Böer, describes a photovoltaic cell and a method for its manufacture. Böer does not suggest nano photovoltaic/solar cells according to the claimed invention.

U.S. Pat. No. 4,368,216, issued on Jan. 11, 1983 to Manassen et al., describes a semiconductor photoelectrode and a method for its manufacture. Manassen et al. does not suggest nano photovoltaic/solar cells according to the claimed invention.

U.S. Pat. No. 4,759,993, issued on Jul. 26, 1988 to Purchandra Pai et al., describes a coated stainless steel article and a method for its manufacture. Pai et al. does not suggest nano photovoltaic/solar cells according to the claimed invention.

U.S. Pat. No. 5,084,107, issued on Jan. 28, 1992 to Mikio Deguchi et al., describes a solar cell electrode structure and a method for its manufacture. Deguchi et al. does not suggest nano photovoltaic/solar cells according to the claimed invention.

U.S. Pat. No. 5,380,371, issued on Jan. 10, 1995 to Tsutomu Murakami, describes a thin film solar cell and a method for its manufacture. Murakami does not suggest nano photovoltaic/solar cells according to the claimed invention.

U.S. Pat. No. 5,389,159, issued on Feb. 14, 1995 to Ichiro Kataoka et al., describes a solar cell module and a method for its manufacture. Kataoka et al. does not suggest nano photovoltaic/solar cells according to the claimed invention.

U.S. Pat. No. 5,428,249, issued on Jun. 27, 1995 to Ippei Sawayama et al., describes a photovoltaic device which has high conversion efficiency and can stably operate over long periods of time. Sawayama et al. does not suggest nano photovoltaic/solar cells according to the claimed invention.

U.S. Pat. No. 5,487,792, issued on Jan. 30, 1996 to David E. King et al., describes a protective diffusion barrier having adhesive qualities for metalized surfaces. King et al. does not suggest nano photovoltaic/solar cells according to the claimed invention.

U.S. Pat. No. 5,641,362, issued on Jun. 24, 1997 to Daniel L. Meier, describes an aluminum alloy junction self-aligned back contact silicon solar cell and a method for its manufacture. Meier does not suggest nano photovoltaic/solar cells according to the claimed invention.

U.S. Pat. Nos. 5,681,402 and 5,861,324, issued on Oct. 28, 1997 and Jan. 19, 1999, respectively, to Hirofumi Ichinose et al., describe a photovoltaic element and a method for its manufacture. Ichinose et al. '402 and '324 do not suggest nano photovoltaic/solar cells according to the claimed invention.

U.S. Pat. No. 5,830,274, issued on Nov. 3, 1998 to Donald B. Jones et al., describes apparatuses for controlling the pattern of a spray of finely divided, charged coating particles projected toward an electrically-isolated and/or oppositely-charged dielectric material. Jones et al. does not suggest nano photovoltaic/solar cells according to the claimed invention.

U.S. Pat. No. 6,008,451, issued on Dec. 28, 1999 to Hirofumi Ichinose et al., describes a photovoltaic device which has high humidity resistance and high reliability throughout a long term use. Ichinose et al. '451 does not suggest nano photovoltaic/solar cells according to the claimed invention.

U.S. Pat. Nos. 6,013,871, 6,160,215, and 6,380,477 B1, issued on Jan. 11, 2000, Dec. 12, 2000, and Apr. 30, 2002, respectively, to Lawrence F. Curtin, describe a photovoltaic device and a method for its manufacture. Curtin '871, '215, and '477 do not suggest nano photovoltaic/solar cells according to the claimed invention.

U.S. Pat. No. 6,051,778, issued on Apr. 18, 2000 to Hirofumi Ichinose et al., describes an electrode structure, a method for its manufacture, and a photo-electricity generating device including the electrode. Ichinose et al. '778 does not suggest nano photovoltaic/solar cells according to the claimed invention.

U.S. Pat. No. 6,093,884, issued on Jul. 25, 2000 to Fumitaka Toyomura et al., describes a solar cell array including a plurality of solar cell modules each including a solar cell element and an electroconductive outer portion. Toyomura et al. does not suggest nano photovoltaic/solar cells according to the claimed invention.

U.S. Pat. No. 6,121,542, issued on Sep. 19, 2000 to Hidenori Shiotsuka et al., describes a photovoltaic device and a method for its manufacture. Shiotsuka et al. does not suggest nano photovoltaic/solar cells according to the claimed invention.

U.S. Pat. No. 6,194,650 B1, issued on Feb. 27, 2001 to Hiroaki Wakayama et al., describes a coated object and a method for its manufacture. Wakayama et al. does not suggest nano photovoltaic/solar cells according to the claimed invention.

U.S. Pat. Nos. 6,206,996 B1 and 6,278,053 B1, issued on Mar. 27, 2001 and Aug. 21, 2001, respectively, to Jack I. Hanoka et al., describe decals and methods for providing an antireflective coating and metallization on a solar cell. Hanoka et al. '996 and '053 do not suggest nano photovoltaic/solar cells according to the claimed invention.

U.S. Pat. No. 6,224,016 B1, issued on May 1, 2001 to Yee-Chun Lee et al., describes an integrated flexible solar cell and a method for its manufacture. Lee et al. does not suggest nano photovoltaic/solar cells according to the claimed invention.

U.S. Pat. No. 6,268,014 B1, issued on Jul. 31, 2001 to Chris Eberspacher et al., describes a method of forming solar cell materials from particulars. Eberspacher et al. does not suggest nano photovoltaic/solar cells according to the claimed invention.

U.S. Pat. No. 6,277,448 B2, issued on Aug. 21, 2001 to Peter R. Strutt et al., describes a thermal spray method for the formation of nanostructured coatings. Strutt et al. does not suggest nano photovoltaic/solar cells according to the claimed invention.

U.S. Pat. No. 6,284,072 B1, issued on Sep. 4, 2001 to Timothy G. Ryan et al., describes multifunctional microstructures and their preparation techniques. Ryan et al. does not suggest nano photovoltaic/solar cells according to the claimed invention.

U.S. Pat. No. 6,359,325 B1, issued on Mar. 19, 2002 to Munir D. Naeem et al., describes a method of forming nan-scale structures from polycrystalline materials and nano-scale structures formed thereby. Naeem et al. does not suggest nano photovoltaic/solar cells according to the claimed invention.

European Patent document EP 0 710 990 A2, published on May 8, 1995, describes a photovoltaic device and a method for its manufacture. European '990 does not suggest nano photo voltaic/solar cells according to the claimed invention.

None of the above inventions and patents, taken either singularly or in combination, is seen to describe the instant invention as claimed.

### SUMMARY OF THE INVENTION

The present invention is a method and apparatus for producing nano photovoltaic/solar cells. Nano photovoltaic/solar cells may each include a layer of plastic, conductive paint on the layer of plastic, dielectric adhesive colloid film on the conductive paint, nano photovoltaic/solar elements in the dielectric adhesive colloid film and contacting the conductive paint, clear conductive coating on the nano photovoltaic/solar elements, and a contact transfer release sheet on the clear conductive coating. The nano photovoltaic/solar elements each include a conductive bottom, a P type layer on the conductive bottom, an N type layer on the P type layer, and a clear conductive top on the N type layer. The nano photovoltaic/solar elements may include more than one P and N junction between the conductive bottom and clear conductive top.

Accordingly, it is a principal aspect of the invention to provide a nano photovoltaic/solar cell including a substrate, a conductive coating on the substrate, a dielectric adhesive colloid film on the conductive coating, nano photovoltaic/solar elements on the dielectric adhesive colloid film, a clear conductive coating on the nano photovoltaic/solar elements, and a sheet on the clear conductive coating.

It is another aspect of the invention to provide a method for producing a nano photovoltaic/solar cell, the method including providing a substrate; spraying the substrate with a conductive coating; providing a dielectric adhesive colloid spray with a nozzle; providing a DC power source; interconnecting a terminal of the DC power source having one polarity to the nozzle of the dielectric adhesive colloid spray; interconnecting a terminal of the DC power source having a polarity opposite the one polarity to a conductive element near the conductive coating; spraying the conductive coating with a film of dielectric adhesive colloid including nano photovoltaic/solar elements from the dielectric adhesive colloid spray; contacting and aligning nano photovoltaic/solar elements in the dielectric colloid film, with one end making contact in the conductive coating, and the opposite end extending in a direction toward the nozzle of dielectric adhesive colloid spray; spraying the nano photovoltaic/solar elements with a clear conductive coating; bonding another sheet on the clear conductive coating; and cutting the sheet of plastic after the bonding step into individual nano photovoltaic/solar cells.

It is a further aspect of the invention to provide an apparatus for manufacturing a nano photovoltaic/solar cell, the apparatus including a die with openings defined therein; a load roll of plastic sheet; a plurality of shields; a first conductive paint spray configured to spray conductive paint; a DC power source; a dielectric adhesive colloid spray configured to spray dielectric adhesive colloid spray including nano photovoltaic/solar elements, the spray having a nozzle interconnected with the DC power source at a first polarity; a metal plate positioned a distance away from the nozzle of the dielectric adhesive colloid spray, the metal plate being interconnected with the DC power source at a polarity opposite the first polarity; a first plurality of heat lamps; a second conductive paint spray configured to spray clear conductive paint; a second plurality of heat lamps; a contact roll configured to bond a transfer release sheet to plastic sheet from said load roll; and a cutter configured to cut plastic sheet from said load roll.

It is an aspect of the invention to provide improved elements and arrangements thereof in nano photovoltaic/solar cells for the purposes described which is inexpensive, dependable and fully effective in accomplishing its intended purposes.

These and other aspects of the present invention will become readily apparent upon further review of the following specification and drawings.

### BRIEF DESCRIPTION OF THE DRAWINGS

FIG. 1 is a front view of a nano photovoltaic/solar element according to the present invention.

FIG. 2A is a top view of a die for producing nano photovoltaic/solar elements according to the invention.

FIG. 2B is a cross-sectional side view of the die shown in FIG. 2A.

FIG. 3 is a side view of a plastic sheet that has been sprayed with glue and upon which are attached nano photovoltaic/solar elements according to the invention.

FIG. 4 is a top view of a nano photovoltaic/solar cell according to the invention.

FIG. 5 is a side view of an apparatus for carrying out a process for producing nano photovoltaic/solar cells according to the invention.

FIG. 6 is a side view of an arrangement for spraying a dielectric adhesive colloid containing nano photovoltaic/solar elements according to the invention onto a conductive substrate.

FIG. 7 is a side view of a conductive substrate that has been sprayed with a dielectric adhesive colloid containing nano photovoltaic/solar elements according to the invention.

FIG. 8 is a side view of another apparatus for carrying out a process for producing nano photovoltaic/solar cells according to the invention.

Similar reference characters denote corresponding features consistently throughout the attached drawings.

### DETAILED DESCRIPTION OF THE PREFERRED EMBODIMENTS

The present invention are nano photovoltaic/solar cells, and a method and apparatus for producing the same. The invention disclosed herein is, of course, susceptible of embodiment in many different forms. Shown in the drawings and described hereinbelow in detail are preferred embodiments of the invention. It is to be understood, however, that the present disclosure is an exemplification of the principles of the invention and does not limit the invention to the illustrated embodiments.

Nano photovoltaic/solar cells according to the invention may each include a layer of plastic, conductive paint on the plastic sheet, glue on the conductive paint, nano photovoltaic/solar elements on the glue, clear conductive coating on the nano photovoltaic/solar elements, and a contact transfer release sheet on the nano photovoltaic/solar elements.

Alternatively, nano photovoltaic/solar cells according to the invention may each include a substrate, conductive paint on the substrate, a discharged and dispersed dielectric adhesive colloid containing nano photovoltaic/solar elements on the substrate, and clear conductive coating on the discharged and dispersed dielectric adhesive colloid containing nano photovoltaic/solar elements.

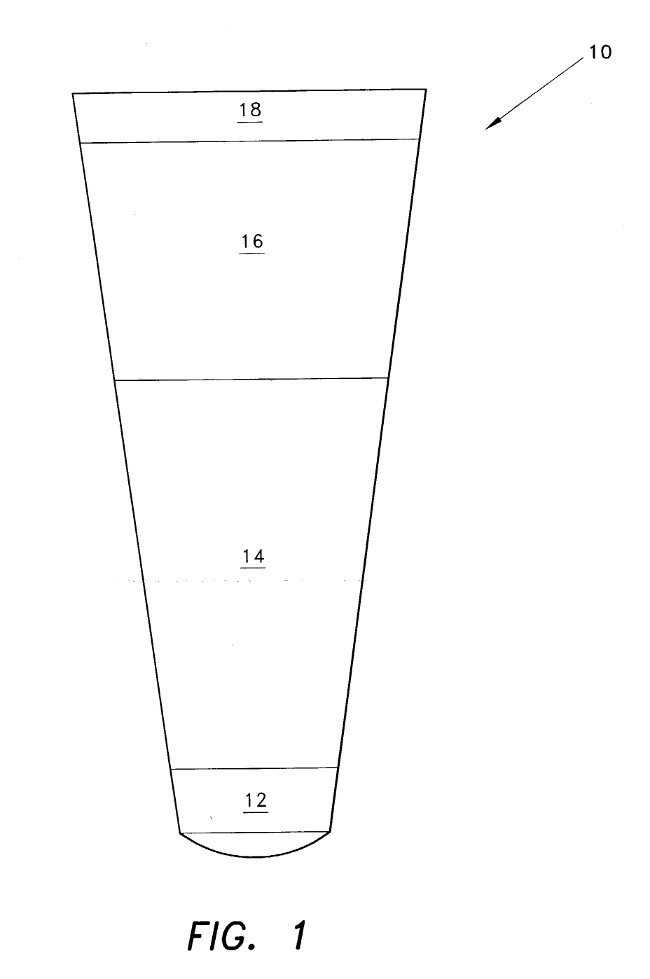

FIG. 1 illustrates how each nano photovoltaic element 10 includes a conductive bottom 12, a P type layer 14 on the conductive bottom 12, an N type layer 16 on the P type layer 14, and a clear conductive top 18 on the N type layer. The nano photovoltaic element 10 may include more than one P and N junction between conductive bottom 12 and clear conductive top 18.

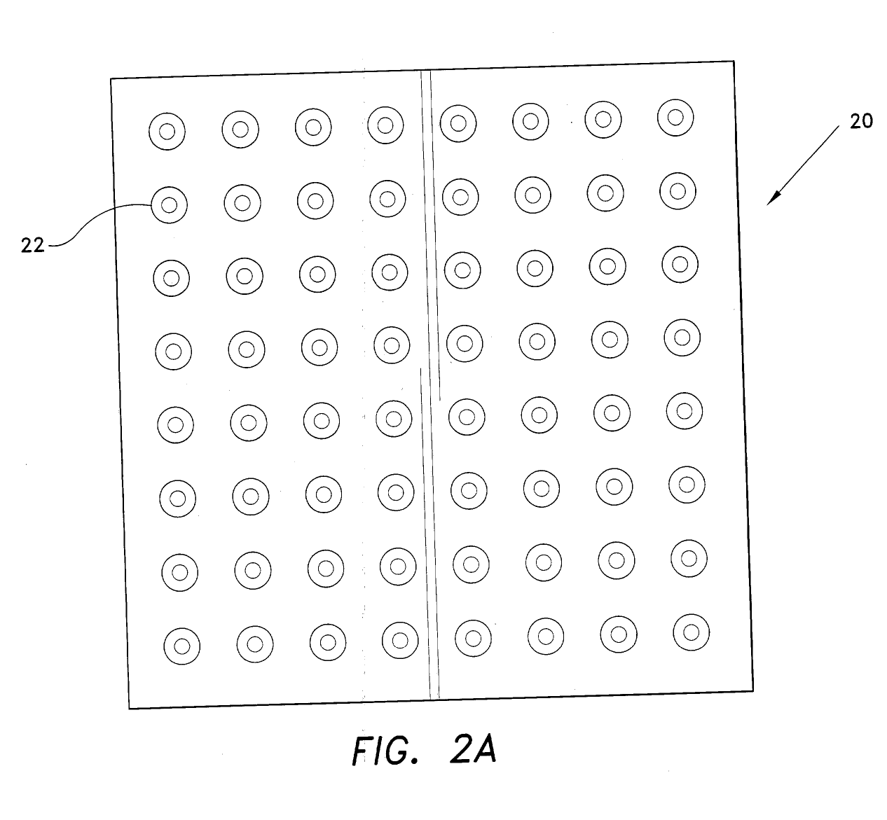

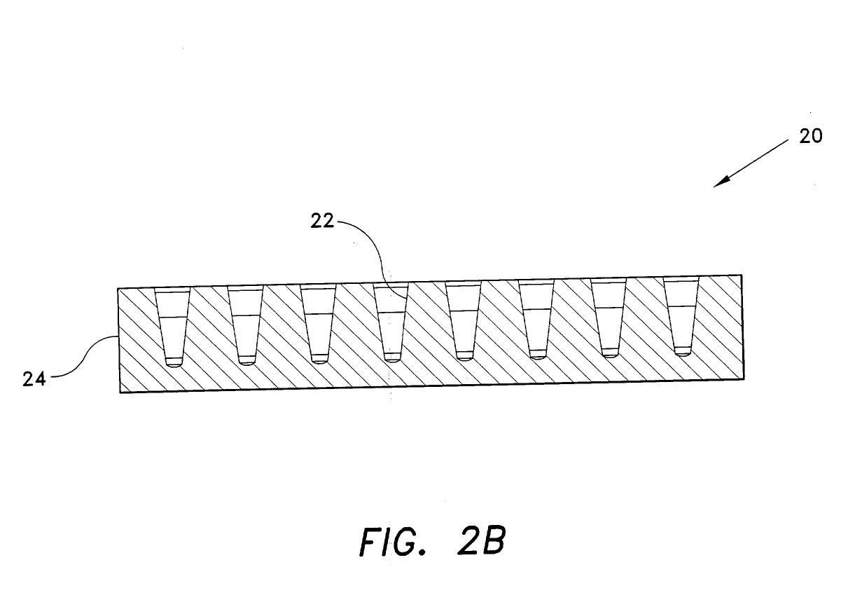

The nano photovoltaic/solar elements 10 are produced by employing a die 20 (see FIGS. 2A and 2B) with openings 22 defined therein that are configured in the form of cones each having a rounded bottom and a side that ends at an opening on a surface of die 20. Die 20 may include any number of cone shaped openings 22 defined therein. The bottom of opening 22 has a smaller diameter than the diameter of the top of opening 22. The nano photovoltaic/solar elements 10 are created by pouring in molten materials into die 20, spinning materials into die 20, injecting into die 20 materials in a vapor stage, placing die 20 in an environment that includes a vapor cloud, pressing in heated materials into die 20, or ion beam implanting materials into die 20.

A conductive bottom 12 is formed by pouring in, spinning in, injecting in, hot pressing in, or ion beam implanting in, conductive materials such as copper, brass, aluminum, molybdenum, or another conductive type material. A P type layer 14 is formed by pouring in, spinning in, injecting in, hot pressing in, or ion beam implanting in, a P type material such as cadmium selenium (CdSe), P doped silicon, P doped gallium, or another P type material, such as ink or dye as described in U.S. Pat. No. 6,013,871, in die 20 over conductive bottom 12. An N type layer 16 is formed by pouring in, spinning in, injecting in, hot pressing in, or ion implanting in, an N type material such as cadmium sulfate (CdS), N doped silicon, N doped gallium, or another N type of material, such as dye or ink as described in U.S. Pat. No. 6,013,870, in the die over P type layer 14. A clear conductive top layer 18 is formed by pouring in, spinning in, injecting in, vapor depositing in, hot pressing in, or ion beam implanting in, a clear conductive material such as zinc oxide doped with aluminum or another clear conductive material in die 20 on N type layer 16.

This process is not limited to a single junction such as described above but may include multiple N and P junctions using different materials between conductive bottom 12 and clear conductive top 18 if desirable. The materials may be amorphous, polycrystal, or single crystal in their structure. The nano photovoltaic/solar elements 10 are then flushed out of die 20 and dried.

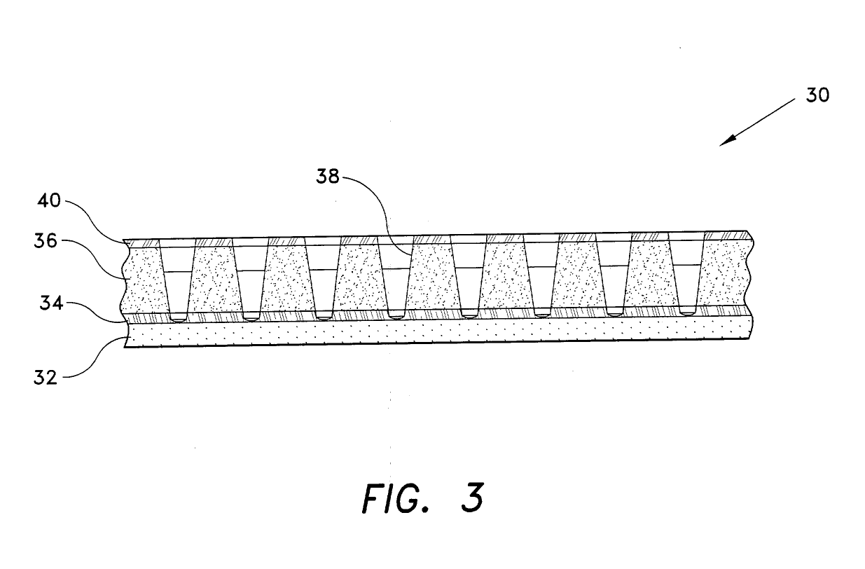

Once nano photovoltaic/solar elements 10 are produced, nano photovoltaic/solar cells may be manufactured. One technique provides a sheet of plastic as a substrate upon which a conductive paint is sprayed. A liquid adhesive, such as glue, paste, mucilage, epoxy, or the like, is then sprayed on the conductive paint. Nano photovoltaic/solar elements are then attached to the liquid adhesive and made to contact the conductive paint. Clear conductive coating is then sprayed onto the nano photovoltaic/solar elements. FIG. 3 illustrates a cross-section of a sheet 30 after these steps upon which a layer of conductive paint 34 is sprayed onto a sheet of plastic 32, a layer of liquid adhesive 36 is sprayed on the conductive paint 34, nano photovoltaic/solar elements 38 are attached into the liquid adhesive to contact the conductive paint 34, and a clear conductive coating 40 is sprayed on the liquid adhesive 36 and the tops of nano photovoltaic elements 38.

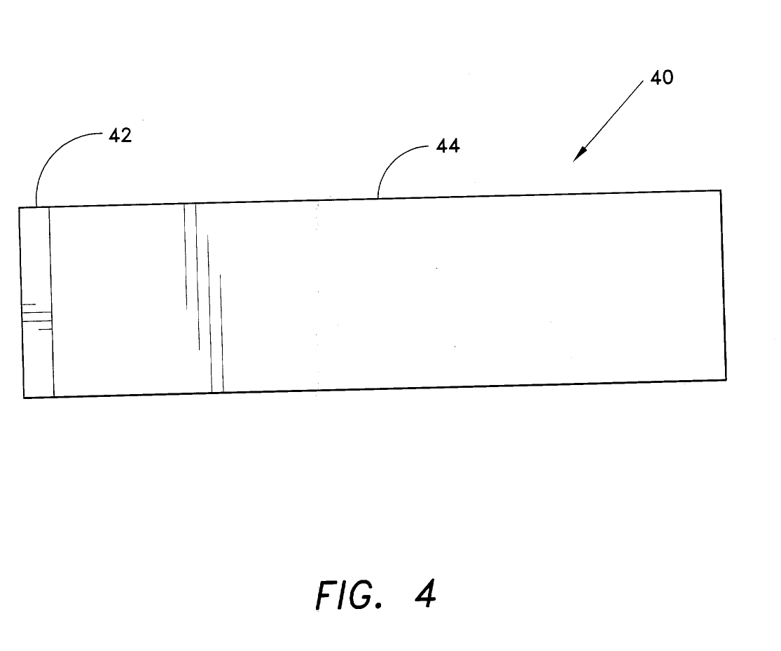

A contact transfer release sheet is then bonded to the clear conductive coating. Alternatively, clear plastic may be used to seal the clear conductive coating. The sheet may then be cut into individual nano photovoltaic/solar cells. FIG. 4 illustrates a top view of this type of nano photovoltaic/solar cell 40 according to the invention. Nano photovoltaic/solar cell 40 includes release sheet or clear plastic 44 and an uncovered edge 42.

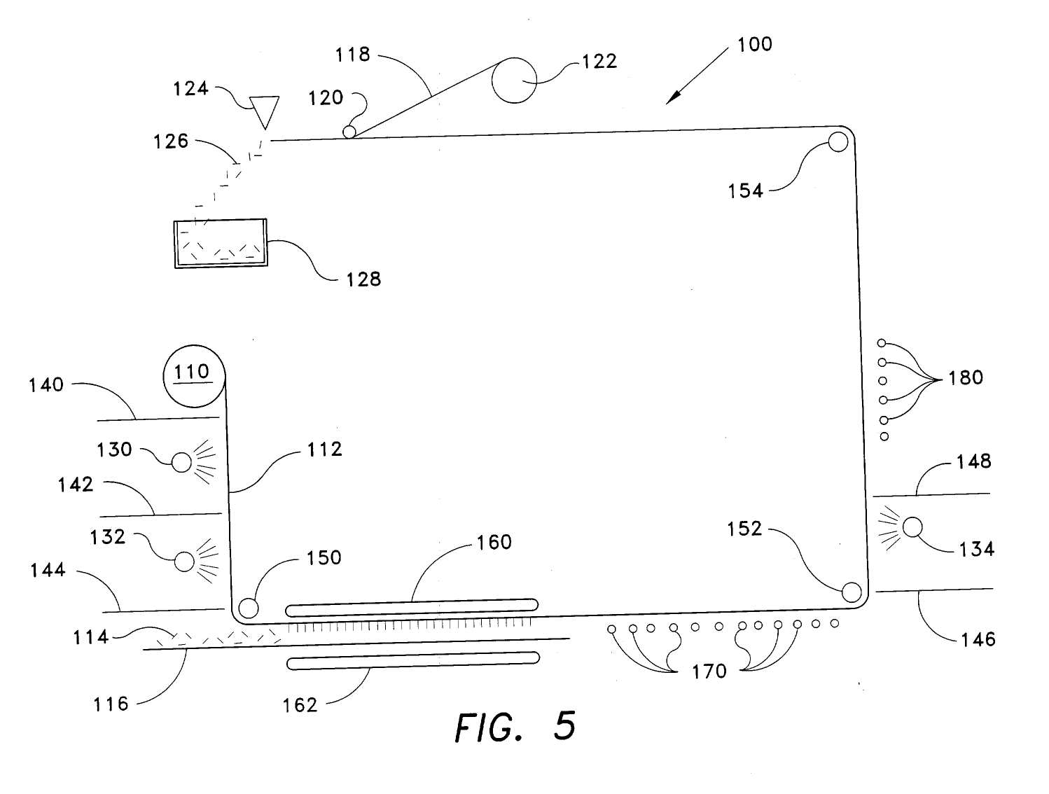

As shown in FIG. 5, an apparatus 100 is shown for carrying out the above described process. A load roll 110 of plastic sheet 112 transfers about a path defined by rolls 150, 152, and 154. Sheet 112 transfers past shield 140 and gets sprayed by a conductive paint spray 130 which sprays conductive paint onto sheet 112. Sheet 112 then passes shield 142 and gets sprayed by a glue spray 132 which sprays a thin layer of dielectric glue onto the conductive paint.

Sheet 112 then transfers past shield 144 and is redirected by contact roll 150 to transfer between a belt 116 and a metal plate 160. Below belt 116 is another metal plate 162. A suitable high voltage is applied between plates 160 and 162 so they function as electrodes. Belt 116 carries nano photovoltaic/solar elements 114 that have been prepared and dried as described above. Nano photovoltaic/solar elements 114, upon entering the electric field between electrodes 160 and 162, stand up and align with the electric field. Nano photovoltaic/solar elements 114 then become charged and fly upward and stick their bottom conductive tips into the dielectric glue and in contact with the conductive paint that has been sprayed onto sheet 112. Sheet 112 then transfers past heat lamps 170 which heat activate the glue and the conductive paint, and more securely adhere nano photo-voltaic/solar elements 114 to the glue and the conductive paint. Heat lamps 170 also photoactivate nano photo-voltaic/solar elements 114.

Sheet 112 is then redirected by contact roll 152 and transfers past shield 146. After passing shield 146, clear conductive coating spray 134 sprays clear conductive coating onto photo-activated nano photovoltaic/solar elements 114. Sheet 112 then transfers past shield 148 and past heat lamps 180. Shields 140, 142, 144, and 148 allow for no glue and no clear conductive coating on a predetermined distance from each edge of sheet 112, such as ¼ inch or the like. Heat lamps 180 further heat activate the materials on sheet 112 and further photoactivate nano photovoltaic/solar elements 114.

Sheet 112 then transfers past contact roll 154 and is redirected to transfer past contact roll 120. Contact roll 120 bonds contact transfer release sheet 118 to the clear conductive coating sprayed onto nano photovoltaic/solar elements 114 by clear conductive coating spray 134. Contact release sheet 118 may have clear silicon applied thereto. Contact release sheet goes on sheet 112 and leaves a predetermined distance from each edge of sheet uncovered, such as ¼ inch or the like. Contact transfer release sheet 118 is removed from contact transfer release roll 122. As an alternative to employing contact transfer release sheet 118, sheet 112 may be sealed in a clear plastic. After contact transfer release sheet 118 is bonded to sheet 112, sheet 112 is transferred past cutter 124 which cuts sheet 112 into individual nano photovoltaic/solar cells 126. The configuration of apparatus 100 may obviously be changed so that it is straight rather than going around corners.

Some changes may be made to the above described process and apparatus for manufacturing nano photovoltaic solar cells. For example, a dielectric adhesive colloid containing nano photovoltaic/solar elements may be sprayed onto a conductive substrate, as opposed to the steps of spraying liquid adhesive on the conductive paint, and then attaching nano photovoltaic/solar elements to the liquid adhesive and making them contact the conductive paint.

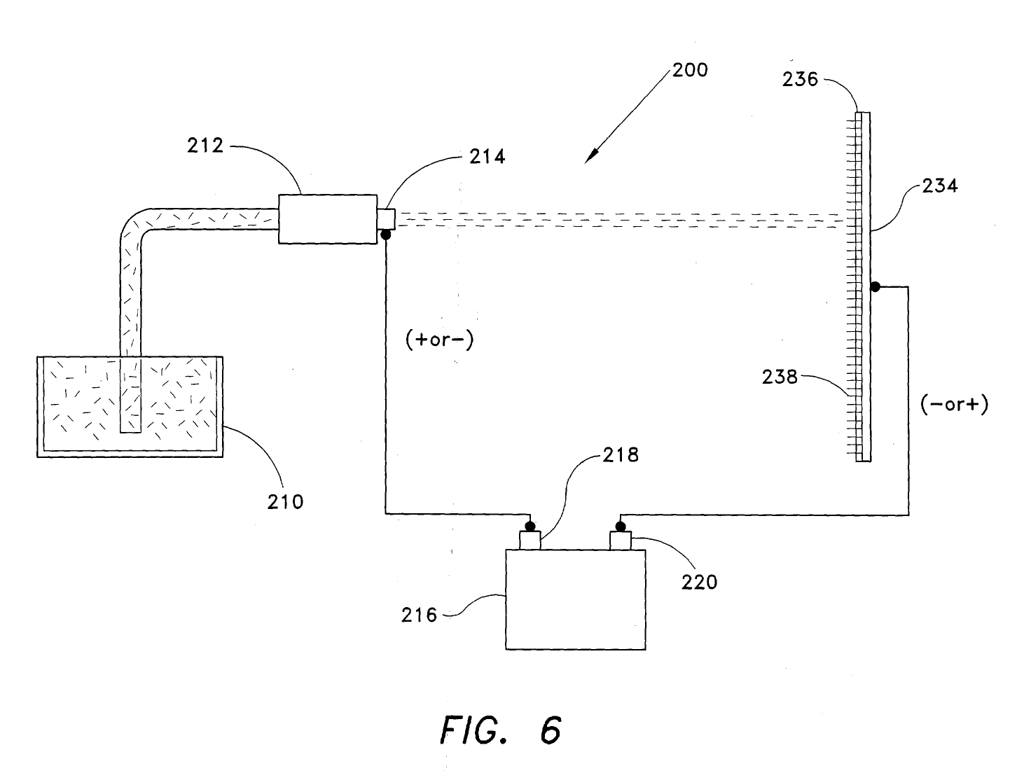

FIG. 6 illustrates an arrangement 200 for spraying a dielectric adhesive colloid containing nano photovoltaic/solar elements onto a conductive substrate. Arrangement 200 generally includes a spray gun configuration, DC power source 216, and conductive substrate 234. The conductive substrate may be configured according to the desires of the user. For example, conductive paint may be applied to a wall, a sheet, or the like. DC power source 216 is electrically interconnected, by wire conductors or the like, at a predetermined volt/amp setting, between nozzle 214 of the spray gun configuration and substrate 234 so that opposing terminals (positive and negative) of DC power source 216 are interconnected with nozzle 214 and substrate 234. The spray gun configuration includes container 210, chamber 212, and nozzle 214.

Container 210 may be filled with a dielectric adhesive colloid containing nano photovoltaic/solar elements produced as described above. The dielectric adhesive colloid is passed as a solid stream under hydrostatic pressure through a preorifice into chamber 212 thereby producing cavitation and partial breakup of the dielectric adhesive colloid. The dielectric adhesive colloid is discharged through an orifice in nozzle 214 and interacts with surrounding air, forming small particles. The small particles of the discharged dielectric adhesive colloid form an expanding spray pattern having a cross sectional shape determined by the geometry of nozzle 214. When the small particles are formed at nozzle 214 of the spray gun configuration, they are charged with a polarity opposite that of substrate 234. As the spray pattern hits substrate 234 a thin film of the dielectric adhesive colloid forms on the conductive substrate. The nano photovoltaic/solar elements in the thin colloid film make contact and align themselves in and/or on the conductive substrate, with a desired end making contact in and/or on the conductive substrate, and the opposite end extending in the direction of charged nozzle 214. The charge of nozzle 214 creates a small depression around the extending ends of the nano photovoltaic/solar elements, allowing them to make contact with a clear conductive coating which will be applied next, as described above.

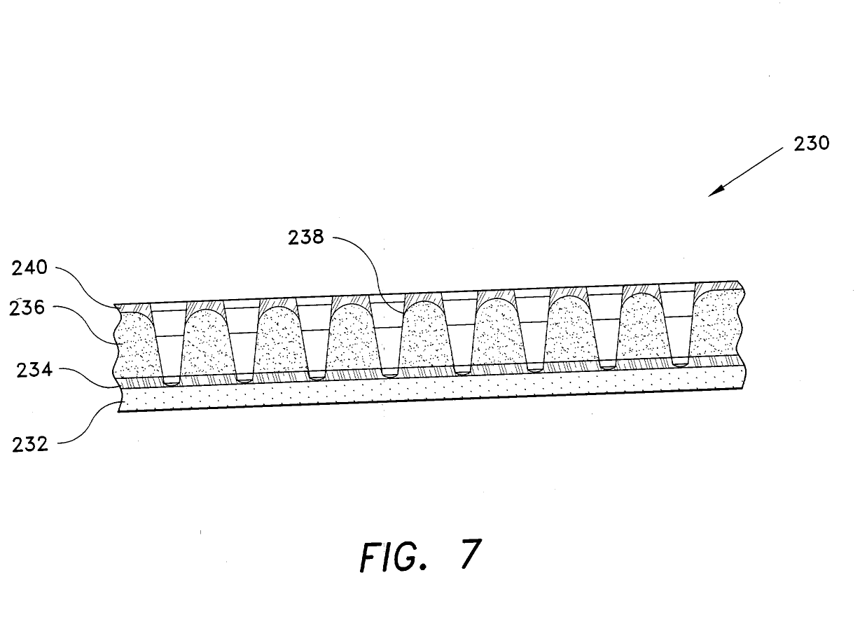

The substrate may be masked to create arrays of nano photovoltaic/solar cells of a desired electrical volt/amp configuration. Conductive coatings may also be used instead of conductive wire to draw off amps. A clear cover may be applied over produced nano photovoltaic/solar cells to protect against damage and the elements. FIG. 7 illustrates a cross-section of a sheet 230 after these steps upon which a layer of conductive paint 234 is sprayed onto substrate 232, such as a wall, a sheet of plastic, or the like, a thin film of a dielectric adhesive colloid 236 containing nano photovoltaic/solar elements is sprayed on conductive paint 234, and a clear conductive coating 40 is sprayed on the dielectric adhesive colloid 236 containing nano photovoltaic/solar elements and the tops of nano photovoltaic elements 238.

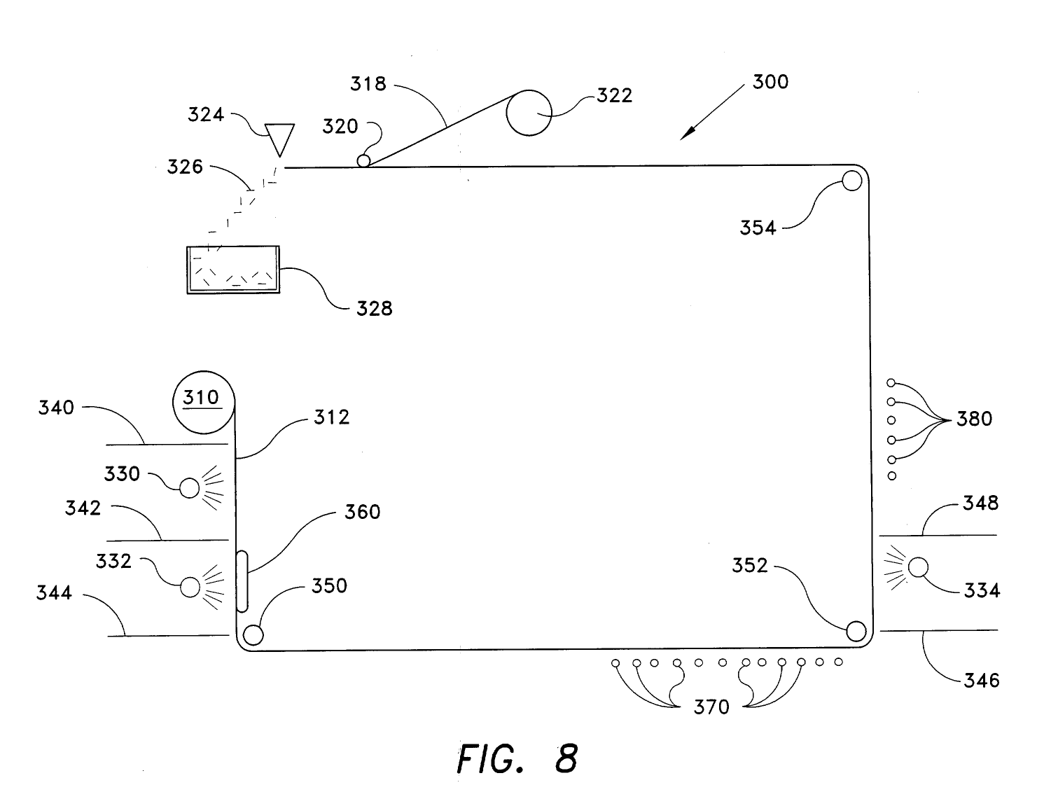

FIG. 8 illustrates an apparatus 300 that may be used for carrying out a nano photovoltaic/solar cell production process that sprays a dielectric adhesive colloid containing nano photovoltaic/solar elements onto a conductive substrate, as described above. A load roll 310 of plastic sheet 312 transfers about a path defined by rolls 350, 352, and 354. Sheet 312 transfers past shield 340 and gets sprayed by a conductive paint spray 330 which sprays conductive paint onto sheet 312. Sheet 312 then passes shield 342 and gets sprayed by a dielectric adhesive colloid spray 332 which sprays a thin film of dielectric adhesive colloid particles onto the conductive paint. A metal plate 360 is placed in contact with the opposite side of sheet 312 that is sprayed with conductive paint and the thin film of dielectric adhesive colloid particles. A DC power source (not shown) is electrically interconnected, by wire conductors or the like, at a predetermined volt/amp setting, between a nozzle of the dielectric adhesive colloid spray 332 and metal plate 360 so that opposing terminals (positive and negative) of the DC power source are interconnected with the nozzle of dielectric adhesive colloid spray 332 and metal plate 360. The nano photovoltaic/solar elements in the thin colloid film make contact and align themselves in the conductive coating, with a desired end making contact in the conductive coating, and the opposite end extending in the direction of the charged nozzle of dielectric adhesive colloid spray 332. The charge of the nozzle creates a small depression around the extending ends of the nano photovoltaic/solar elements.

Sheet 312 then transfers past shield 144 and is redirected by contact roll 350 to transfer sheet 312 past heat lamps 370 which heat activate the thin dielectric adhesive colloid film and the conductive paint, and more securely adhere the nano photovoltaic/solar elements in the thin dielectric adhesive colloid film to the conductive paint. Heat lamps 370 also photoactivate the nano photo-voltaic/solar elements.

Sheet 312 is then redirected by contact roll 352 and transfers past shield 346. After passing shield 346, clear conductive coating spray 334 sprays clear conductive coating onto the thin dielectric adhesive colloid film and photo-activated nano photovoltaic/solar elements extending therefrom. Sheet 312 then transfers past shield 348 and past heat lamps 380. Shields 340, 342, 344, and 348 allow for no thin dielectric colloid film and no clear conductive coating on a predetermined distance from each edge of sheet 312, such as ¼ inch or the like. Heat lamps 380 further heat activate the materials on sheet 312 and further photoactivate the nano photovoltaic/solar elements.

Sheet 312 then transfers past contact roll 354 and is redirected to transfer past contact roll 320. Contact roll 320 bonds contact transfer release sheet 318 to the clear conductive coating sprayed onto the nano photovoltaic/solar elements by clear conductive coating spray 334. Contact release sheet 318 may have clear silicon applied thereto. Contact release sheet goes on sheet 312 and leaves a predetermined distance from each edge of sheet uncovered, such as ¼ inch or the like. Contact transfer release sheet 318 is removed from contact transfer release roll 322. As an alternative to employing contact transfer release sheet 318, sheet 312 may be sealed in a clear plastic. After contact transfer release sheet 318 is bonded to sheet 312, sheet 312 is transferred past cutter 324 which cuts sheet 312 into individual nano photovoltaic/solar cells 326. The configuration of apparatus 300 may obviously be changed so that it is straight rather than going around corners.

In nano photovoltaic/solar cells according to the invention, there is no light loss through diffusion, dispersion, or reflection. One hundred percent of the light that hits the nano photovoltaic/solar cell's top is utilized. The light that travels down the nano photovoltaic/solar cell activates the cell. By creating multiple P and N junctions between the clear conductive bottom and top, or stacking, it is possible to reach efficiencies approaching eighty percent.

While the invention has been described with references to its preferred embodiment, it will be understood by those skilled in the art that various changes may be made and equivalents may be substituted for elements thereof without departing from the true spirit and scope of the invention. In addition, many modifications may be made to adapt a particular situation or material to the teaching of the invention without departing from its essential teachings.

I claim:

1. A nano photovoltaic/solar cell comprising:
a substrate;
a conductive coating on the substrate;
a dielectric adhesive colloid film on the conductive coating;
nano photovoltaic/solar elements on the dielectric adhesive colloid film;
a clear conductive coating on the nano photovoltaic/solar elements; and
a sheet on the clear conductive coating.

2. The nano photovoltaic/solar cell according to claim 1, wherein said substrate is a plastic sheet.

3. The nano photovoltaic/solar cell according to claim 1, wherein said nano photovoltaic/solar elements each comprise:
a conductive bottom;
a clear conductive top; and
at least one P and N junction between said conductive bottom and said clear conductive top, wherein a P type layer contacts said conductive bottom and an N type layer contacts said clear conductive top.

4. The nano photovoltaic/solar cell according to claim 3, wherein said conductive bottom is selected from the group consisting of copper, brass, aluminum, and molybdenum.

5. The nano photovoltaic/solar cell according to claim 3, wherein said P type layer is material selected from the group consisting of cadmium selenium, P doped silicon, and P doped gallium.

6. The nano photovoltaic/solar cell according to claim 3, wherein said N type layer is material selected from the group consisting of cadmium sulfate, N doped silicon, and N doped gallium.

7. The nano photovoltaic/solar cell according to claim 3, wherein said clear conductive top is zinc oxide doped with aluminum.

8. The nano photovoltaic/solar cell according to claim 1, wherein said sheet on said clear conductive coating is a contact transfer release sheet.

9. The nano photovoltaic/solar cell according to claim 1, wherein said sheet on said clear conductive coating is a clear plastic sheet.

10. A method for producing a nano photovoltaic/solar cell, the method comprising:
providing a substrate;
spraying the substrate with a conductive coating;
providing a dielectric adhesive colloid spray with a nozzle;
providing a DC power source;
interconnecting a terminal of the DC power source having one polarity to the nozzle of the dielectric adhesive colloid spray;
interconnecting a terminal of the DC power source having a polarity opposite the one polarity to a conductive element near the conductive coating;
spraying the conductive coating with a film of dielectric adhesive colloid including nano photovoltaic/solar elements from the dielectric adhesive colloid spray;
contacting and aligning nano photovoltaic/solar elements in the dielectric colloid film, with one end making contact in the conductive coating, and the opposite end extending in a direction toward the nozzle of dielectric adhesive colloid spray;
spraying the nano photovoltaic/solar elements with a clear conductive coating;
bonding another sheet on the clear conductive coating; and
cutting the sheet of plastic after the bonding step into individual nano photovoltaic/solar cells.

11. The method for producing a nano photovoltaic/solar cell according to claim 10, wherein said bonding step further comprises providing a contact transfer sheet as said another sheet.

12. The method for producing a nano photovoltaic/solar cell according to claim 10, wherein said bonding step further comprises providing a clear plastic sheet as said another sheet.

13. An apparatus for manufacturing a nano photovoltaic/solar cell, said apparatus comprising:
a die with openings defined therein;
a load roll of plastic sheet;
a plurality of shields;
a first conductive paint spray configured to spray conductive paint;
a DC power source;
a dielectric adhesive colloid spray configured to spray dielectric adhesive colloid spray including nano photovoltaic/solar elements, the spray having a nozzle interconnected with the DC power source at a first polarity;
a metal plate positioned a distance away from the nozzle of the dielectric adhesive colloid spray, the metal plate being interconnected with the DC power source at a polarity opposite the first polarity;
a first plurality of heat lamps;
a second conductive paint spray configured to spray clear conductive paint;
a second plurality of heat lamps;
a contact roll configured to bond a transfer release sheet to plastic sheet from said load roll; and
a cutter configured to cut plastic sheet from said load roll.

14. The apparatus for manufacturing a nano photovoltaic/solar cell according to claim 13, wherein said die has openings defined therein that are each configured in a form of a cone having a rounded bottom and a side that ends at an opening on a surface of said die.
